(19) United States
(12) Patent Application Publication
(10) Pub. No.: US 2014/0299577 A1
(43) Pub. Date: Oct. 9, 2014

(54) APPARATUS AND METHOD FOR SURFACE PROCESSING OF A SUBSTRATE

(71) Applicants: Carl Zeiss SMT GmbH, Oberkochen (DE); Carl Zeiss Microscopy GmbH, Jena (DE)

(72) Inventors: Hin Yiu Anthony Chung, Ulm (DE); Michel Aliman, Oberkochen (DE); Gennady Fedosenko, Aalen (DE); Albrecht Ranck, Aalen (DE); Leonid Gorkhover, Ulm (DE)

(21) Appl. No.: 14/312,363

(22) Filed: Jun. 23, 2014

Related U.S. Application Data
(63) Continuation of application No. PCT/EP2013/050152, filed on Jan. 7, 2013.

(30) Foreign Application Priority Data
Jan. 9, 2012 (DE) 102012200211.1

(51) Int. Cl. H01J 37/32; C23C 16/44

(52) U.S. Cl. CPC H01J 37/32009; C23C 16/44
USPC 216/59; 156/345.24; 118/712; 427/569

(57) ABSTRACT

The invention relates to an apparatus for surface processing on a substrate, for example for applying a coating to the substrate or for removing a coating from the substrate, wherein the apparatus comprises: a chamber enclosing an interior and serving for arranging the substrate for the surface processing, a process gas analyser for detecting at least one gaseous constituent of a residual gas atmosphere formed in the interior, wherein the process gas analyser comprises an ion trap for storing the gaseous constituent to be detected, and an ionization device for ionizing the gaseous constituent. The invention also relates to an associated method for monitoring surface processing on a substrate.

### CROSS-REFERENCE TO RELATED APPLICATIONS

This application is a continuation of, and claims benefit under 35 USC 120 to, international application PCT/EP2013/050152, filed Jan 7, 2013, which claims priority to German Patent Application No. 10 2012 200 211.1 filed on Jan. 9, 2012, the entire contents of which are incorporated by reference in the disclosure of this application.

### BACKGROUND OF THE INVENTION

The invention relates to an apparatus and a method for surface processing of a substrate.

For carrying out surface processing on a substrate, for example for coating a substrate by vapour deposition (“physical vapour deposition”, PVD, or “chemical vapour deposition”, CVD) or for removing a coating from the substrate, e.g. via an etching process, the (if appropriate coated) substrate to be processed is typically arranged in a process or transfer chamber with a residual gas atmosphere prevailing therein. For carrying out surface processing processes such as are required in semiconductor electronics or in optoelectronics, for example, it has proved to be advantageous to monitor the gas composition in the residual gas atmosphere during the process in order to observe gas decomposition processes or gas transport processes or in order to carry out contamination monitoring in order, in this way, to optimize the processing process with regard to process quality, throughput times, “uptime” and economic viability.

For a residual gas analysis it is possible to use quadrupole mass spectrometers in which a hot incandescent wiring (also called filament) is used as ionization source, the wire consisting of a metal, e.g. of tungsten. However, this type of mass spectrometer is not suitable for direct use at high operating pressures (e.g. up to 1000 mbar) or requires complex differential pumping systems. Moreover, the measurement time for a scan in the mass range of 1 amu to 200 amu with a high sensitivity of e.g. approximately 10⁻¹³ mbar is in the range of several minutes. The use of a filament as ionization source also includes the risk of the filament burning through in the event of sudden pressure increases (e.g. during ventilation), in association with maintenance or repair times and, if appropriate, contamination of the chamber in which the heating wire is arranged with metal vapour produced as the filament burns through.

### OBJECT OF THE INVENTION

It is an object of the invention to provide an apparatus and a method for surface processing on a substrate which make it possible to detect small quantities of gas constituents in a residual gas atmosphere even at high residual gas pressures and in particular in real time.

### SUBJECT MATTER OF THE INVENTION

This object is achieved via an apparatus for surface processing on a substrate, in particular for applying a coating to the substrate or for (if appropriate partly) removing a coating from the substrate, comprising: a chamber enclosing an interior and serving for arranging the substrate during the surface processing, a process gas analyser for detecting at least one gaseous constituent of a residual gas atmosphere formed in the interior, wherein the process gas analyser comprises an ion trap for (three-dimensional) storing of the gaseous constituent, and an ionization device for ionizing the gaseous constituent.

In contrast to the process or residual gas analysers which are known from the prior art and in which the ionized gas constituents only momentarily pass the electromagnetic fields of the quadrupole mass spectrometer, without being stored in the fields, the provision of the ion trap makes it possible to increase the detection sensitivity of the process gas analyser, since the ionized gaseous constituent is trapped in all three spatial dimensions, i.e. has stable oscillations in all three spatial dimensions, and is thus available for measurement for a longer time (typically 1 ms or more, preferably less than 1 second or 100 ms). The dimensions of the space in which the ionized gaseous constituent(s) is/are trapped are typically less than 50 cm×50 cm×50 cm, preferably less than 20 cm×20 cm×20 cm. In contrast thereto, differentially pumped quadrupole mass spectrometers of conventional design (having rod electrodes) have considerable disadvantages with regard to the sensitivity and dynamic range, since they carry out a serial mass filtering and cannot accumulate ions or cannot select ion groups in a targeted manner.

In the ion trap or a mass spectrometer connected thereto, by contrast, for the purpose of detecting the gaseous constituent it is possible to carry out mass spectrometry which is also suitable for detecting extremely small concentrations of gaseous substances. Ion trap mass spectrometers generally operate discontinuously, that is to say that an analysis of the ion number can take place after a predefined accumulation time (e.g. less than 100 ms). With the aid of ion trap mass spectrometers, multiple repetition of the ion excitation and mass selection is furthermore possible, without a further assembly being required for this purpose. In particular, if appropriate an accumulation of the substance to be detected and a separation of the substance to be detected from further substances present in the residual gas atmosphere can be performed in an ion trap, as will be described in greater detail further below.

The ionization device can be arranged in the ion trap itself or can be embodied as a separate structural unit. In particular, it is also possible to use an ionization device which is already provided in the apparatus anyway for carrying out the surface processing, such that an additional ionization device can be dispensed with. This is the case, for example, if, during plasma-enhanced chemical vapour deposition, the process gas is ionized via a plasma in the reaction chamber.

Although the use of an ion trap or of an ion trap mass spectrometer for detecting contaminating substances in an EUV lithography apparatus is known from WO 2010/022815 A1 in the name of the present applicant, the method described therein or the apparatus described therein relates exclusively to the detection of contaminating substances in an EUV lithography apparatus, but not to process or contamination monitoring in apparatuses for the surface treatment (coating or etching treatment) of a substrate or of coatings applied thereon. In the present use, the process gas analyser or the ion trap can be provided in the (process or transfer) chamber in which the substrate is also arranged, the process gas analyser can be flanged to the chamber or it can, if appropriate, be situated in an adjoining chamber. However, the ion trap can also be arranged in a gas feed or in a gas discharge through which e.g. process gases can be introduced into the chamber or conducted out of the latter. It is also possible to arrange the ion trap in a pump channel that serves for evacuating the housing or the interior or for pumping away a purging or background gas. It goes without saying that, if appropriate, it is also possible to provide more than one process gas analyser in the apparatus.

In one embodiment the ionization device is designed to set the energy provided for the ionization in a manner dependent on the gaseous constituent to be detected. The possibility of (ideally continuously) setting or coordinating the energy provided by the ionization device to or with the gaseous constituent to be detected, to put it more precisely to or with the ionization energy thereof, has proved to be advantageous since this makes possible both an ionization of all types of gas molecules (broadband ionization) and a selective, narrowband ionization of selected molecules without the ionization of surrounding molecules (e.g. carrier gas). Consequently, selected types of molecule (e.g. of contaminating substances, of process-relevant gaseous constituents in the residual gas atmosphere, e.g. dopants, etc.) can be detected or monitored in a targeted manner with the ion trap. For setting the ionization energy, the ionization device or the apparatus can have a control device that makes possible the coordination mentioned above.

In a further embodiment, the ionization device is selected from the group comprising: plasma generator, in particular atmospheric pressure plasma generator, laser and field emission device, in particular electron gun. The ionization can advantageously be effected by the generation of a plasma, in particular of an atmospheric pressure plasma. For the purpose of generating atmospheric pressure plasmas, e.g. a radio-frequency discharge can be ignited between two electrodes in order to generate a corona discharge. It is also possible to use a dielectrically impeded radio-frequency discharge. In the case of this form of excitation, a (thin) dielectric that serves as a dielectric barrier is situated between the electrodes in order to generate a plasma in the form of a multiplicity of spark discharges and in this way to ionize a gas stream situated between the electrodes. It is also possible to use a plasma nozzle in which a pulsed arc is generated via a radio-frequency discharge, or to use a piezo-material for the plasma excitation (at atmospheric pressure), for example as explained in WO 2007/006298 A2. It goes without saying that the plasma generator can also be designed for generating or for exciting a plasma, in particular an atmospheric pressure plasma, in a manner different from that described above. Depending on the use, a (pulsed) laser or an electron gun (for ionizing gas molecules by impact ionization) can also serve for ionization. In the case of the plasma generator, the energy provided for the ionization can be set by the setting of the energy (voltage and also, if appropriate, frequency) made available for the excitation. The laser or a laser system as ionization source can also be designed for generating a tunable or settable laser wavelength in order to vary the energy provided for the ionization. The same applies to the use of a field emission device, in particular in the form of an electron gun for generating concentrated or directed electron beams, which can likewise be designed to set or vary the kinetic energy of the accelerated electrons.

In a further embodiment, the apparatus is designed to carry out a surface treatment on the substrate which is selected from the group comprising: chemical vapour deposition (CVD), metal organic chemical vapour deposition (MOCVD), metal organic chemical vapour phase epitaxy (MOVPE), plasma-enhanced chemical vapour deposition (PECVD), atomic layer deposition (ALD), physical vapour deposition (PVD) and plasma etching processes.

In the case of chemical vapour deposition, a solid is deposited from the vapour phase on a (generally heated) surface of a substrate on account of a chemical reaction. In the case of metal organic chemical vapour deposition, a solid layer of a metallo-organic precursor is deposited from the vapour phase. Metal organic chemical vapour phase epitaxy constitutes a special case of metal organic chemical vapour deposition that serves for producing (mono)crystalline layers on (generally) crystalline substrates. In the methods described above, the deposition is not necessarily effected in a high vacuum but rather at moderate pressures (if appropriate up to approximately 1000 mbar). Atomic layer deposition is likewise a modified CVD method in which generally monocrystalline (epitaxial) layers are deposited, wherein a metallo-organic precursor and a further reactant, if appropriate a further precursor, are alternately admitted into the reaction chamber. The chemical reactions used in atomic layer deposition are generally so-called self-limiting reactions in which the layer growth in each case remains limited to a monolayer, which makes possible a precise setting of the layer thickness. In the case of PECVD, the chemical deposition is enhanced by a plasma. The plasma serves for the activation (dissociation) of the molecules of the reaction gas in order to promote or bring about the layer deposition. The plasma can be generated directly with the substrate to be coated (direct plasma method), or in a separate chamber (remote plasma method). In the case of physical vapour deposition, the deposition is effected from the vapour phase via physical processes, that is to say that no chemical reaction takes place on the surface to be coated.

Plasma etching processes are material-removing methods or methods that pattern the treated material. In the case of so-called plasma etching, the material removal is effected via a chemical reaction with the material to be removed. In the case of so-called plasma-enhanced etching, also referred to as reactive ion etching (RIE), the chemical reaction is amplified by the bombardment of the material to be removed with ions, since the ions weaken the chemical bonds at the treated surface.

In a further embodiment, the ion trap is selected from the group comprising: Fourier transform (FT) ion trap, in particular FT ion cyclotron resonance trap (FT-ICR trap), Penning trap, toroidal trap, quadrupole ion trap, Paul trap, linear trap, Orbitrap, EBIT and RF buncher. The use of an FT ion trap, in particular, makes it possible to realize fast measurements (with scan times in the seconds range or less, e.g. in the milliseconds range, for instance 100 ms or less, yet typically more than 1 ms). With this type of trap, the induced current generated by the trapped ions which have stable oscillations in all three spatial dimensions on the measurement electrodes is detected and amplified in a time-dependent manner. Subsequently, this time dependence is converted to the frequency domain via a fast Fourier transform and the mass dependence of the resonant frequencies of the ions is used to convert the frequency spectrum into a mass spectrum. Mass spectrometry via a Fourier transform can be carried out for the purpose of carrying out fast measurements in principle using different types of ion trap (e.g. the types described above), the combination with the so-called ion cyclotron resonance trap being the most common. The FT-ICR trap constitutes a modification of the Penning trap in which the ions are injected into alternating electric fields and a static magnetic field. In the FT-ICR trap, mass spectrometry can be implemented via cyclotron resonance excitation. In a modification thereof, the Penning trap can also be operated with an additional buffer gas, wherein, by virtue of the buffer gas in combination with a magnetron excitation via an electric dipole field and a cyclotron excitation via an electric quadrupole field, it is possible to produce a mass selection by spatial separation of the ions, such that the Penning trap can also be used for separating the substance to be detected from other substances. Since, with this type of trap, the buffer gas generally has a motion-damping and thus “cooling” effect on the injected ions, this type of trap is also referred to as a “cooler” trap. The so-called toroidal trap, by comparison with a conventional quadrupole trap, makes possible a more compact design in conjunction with a substantially identical ion storage capacity, cf. e.g. the article “Miniature Toroidal Radio Frequency Ion Trap Mass Analyzer”, by Stephen A. Lammert et al., J. Am. Soc. Mass Spectrom. 2006, 17, pages 916 to 922. The linear trap is a modification of the quadrupole trap or Paul trap in which the ions are not held in a three-dimensional quadrupole field, but rather via an additional marginal field in a two-dimensional quadrupole field in order to increase the storage capacity of the ion trap. The so-called Orbitrap has a central, spindle-type electrode around which the ions are held by the electrical attraction on circular paths, wherein decentralized injection of the ions produces an oscillation along the axis of the central electrode which generates signals in the detector plates, which signals can be detected in a manner similar to that in the case of the FT-ICR trap (by FT). An EBIT (Electron Beam Ion Trap) is an ion trap in which the ions are generated by impact ionization via an ion gun, wherein the ions generated in this way are attracted by the electron beam and trapped by the latter. The ions can also be stored in an RF (radio-frequency) buncher, e.g. a so-called RFQ (quadrupole) buncher, see e.g. Neumayr, Juergen Benno (2004): “The buffer-gas cell and the extraction RFQ for SHIPTRAP”, Dissertation, LMU Munich: Faculty of Physics. It goes without saying that, besides the types of traps mentioned above, it is also possible to use other types of ion traps for residual gas analysis which, if appropriate, can be combined with an evaluation using a Fourier transform.

The ion trap can in particular also be designed for detecting the gaseous constituent. In this case, the electrodes of the ion trap, which are provided for generating an (alternating) electric and/or magnetic field, can simultaneously also serve for detecting ions having specific atomic mass numbers, by determining the variation of the alternating field on account of the ions present in the ion trap, as is the case e.g. for the FT-ICR trap described above.

In one embodiment, an ion optical unit is arranged between the ionization device and the ion trap. In this way, the ions generated via the ionization device can be decelerated or concentrated before they reach the ion trap or are introduced into the latter. For this purpose, the ion optical unit can have field generating devices for generating electric and/or magnetic fields which bring about a deflection or concentration of the ions.

In one embodiment, the ion trap is designed to accumulate the gaseous constituent. As a result of the accumulation, during the storage time, it is possible to increase the signal-to-noise ratio of the gaseous constituent to be examined relative to other gaseous constituents or the rest of the residual gas, the noise behaviour and/or the detection threshold of the detector used in the process gas analyser.

In a further embodiment, the ion trap is designed to isolate the gaseous constituent to be detected from other gaseous constituents. In addition or as an alternative to the accumulation, the gaseous constituent can be prepared during the storage time, that is to say that the gaseous constituent can be isolated from the other gaseous constituents in the residual gas atmosphere and thereby detected, without an accumulation also being absolutely necessary for this purpose. In this case, the ion trap can be used for the (spatial) separation of ions having different mass numbers. During the accumulation phase, optionally all ions can be held or stored in the ion trap or individual ion masses can be selectively removed from the ion trap. The selective removal of ions from the ion trap can be realized e.g. by applying or generating an alternating field that directs ions having selected masses onto unstable paths. The selective removal of undesired ions or ion masses (e.g. of carrier gas) from the ion trap makes it possible to avoid saturation of the ion trap and to significantly increase the measurement dynamic range.

Alternatively or additionally, it is also possible to equip the process gas analyser with a mass filter for separating the gaseous constituent to be detected from other gaseous constituents of the residual gas atmosphere. The mass filter can be e.g. a conventional quadrupole filter for mass separation.

In a further embodiment, the apparatus comprises a gas-binding material for the accumulation of the gaseous constituent. The gas-binding material can be an absorber or a filter which passively takes up the gaseous constituent to be detected. The gaseous constituent or the decomposition products thereof, i.e. molecular fragments of the constituent or substance to be detected, can be released from the gas-binding material by stimulated desorption (thermally or by irradiation) in order then to be analysed as strong outgassing. The gas-binding material can be regenerated cyclically e.g. at a high temperature (in a separate (vacuum) region). It goes without staying that the gas-binding material can also be cooled in order to accelerate the accumulation. The gas-binding material can be arranged in the ion trap itself or in a separate chamber. The ionization of the accumulated gas constituent can likewise be effected in the ion trap itself or in the separate chamber before this gas constituent is fed to the ion trap.

The apparatus can in particular also comprise a pump device for pumping the gas constituent to be detected through the gas-binding material. In this case, an active accumulation is effected by the residual gas being conducted through the gas-binding material as filter, wherein the gas-binding material preferably has a large surface area and is porous, in particular. One class of materials which satisfies these requirements is zeolites, for example.

In a further preferred embodiment, the apparatus comprises a cooling unit for cooling a surface for freezing out or condensing the gaseous constituent and preferably a heating unit or an irradiation device for irradiating the surface with light or with electron beams for the subsequent desorption of the gaseous constituent from the surface. In this way, a thermal accumulation of the substance to be detected can take place, wherein a detection can be effected by a fast thawing or evaporation of the substance to be detected via the heating unit together with subsequent temperature-controlled desorption of the evaporated or decomposed species (molecular fragments). The heating/cooling unit can be integrated into the ion trap, in which case the ionization of the accumulated substance has to take place in the ion trap. Alternatively, the heating/cooling unit can be arranged in a separate chamber in which the accumulated gas constituent is firstly ionized before being fed to the ion trap.

Via the thawing of a cooling finger, e.g. a gas species frozen out or condensed in a targeted manner can be rapidly desorbed, which generates a partial pressure that is orders of magnitude higher than that partial pressure which prevails at normal residual gas density with respect to the substance to be detected in the residual gas atmosphere. Besides thawing the cooling finger, it is also possible to irradiate the latter via an irradiation device, for example using an electron gun (E-gun) or using a laser to transfer the condensed or frozen-out substances for detection to the gas phase. The irradiation wavelength can be e.g. UV light or infrared light, if appropriate also light in the visible spectral range.

In particular, the cooling unit and/or the heating unit can also be connected to a control device for setting the temperature of the surface. The control device can serve for setting a temperature at the surface formed at a cooling finger, for example, at which the gas constituent to be detected, but not the background gas itself, is frozen out. The temperature at which the background gas freezes out or condenses is dependent on the condensation temperature of the background gas used, which is approximately 4.2 K in the case of helium, approximately 20.3 K in the case of hydrogen, approximately 87.3 K in the case of argon and approximately 120 K in the case of krypton. By choosing the temperature above these values, it is possible for a selective accumulation of the gas constituent to be effected without impairment by the background gas.

As an alternative or in addition to the irradiation device for irradiating the coolable surface, the apparatus can also comprise an irradiation device, in particular an electron gun or a laser, for the desorption of the substance to be detected from the gas-binding material. Appropriate irradiation devices include, in particular, light sources or electron sources with the aid of which the substance to be detected can be removed by non-thermal or, if appropriate, by thermal desorption from the gas-binding material or the coolable surface and in this case, if appropriate, can simultaneously be ionized, such that the irradiation device simultaneously serves as an ionization device.

In a further embodiment, the chamber has a gas inlet and/or gas outlet controllable in a manner dependent on a detected quantity of the gaseous constituent, that is to say a gas inlet and/or gas outlet which can be opened or closed in a manner dependent on a control signal. This is advantageous in particular in the case of surface processing in the form of atomic layer deposition in which the precursor and at least one further reactant as explained above are introduced alternately (in a pulsed manner) into the chamber, wherein purging intermissions for removing the unused precursor and/or reactant are present between two successive pulses. The purging intermissions should be as short as possible (typically in the seconds range), although two-dimensional monolayer deposition is generally not possible if the purging intermissions are too short. If the purging intermissions are too long, however, the contamination level per monolayer in the partial pressure range of 10⁻¹² mbar to 10⁻¹⁴ mbar rises, as a result of which the deposition quality deteriorates and the throughput time increases unnecessarily. By measuring the partial pressure or the concentration of the gas constituent to be detected, e.g. of the precursor, of the reactant and/or of contaminating reaction products, it is possible to monitor or optimize the (valve) switching processes for the purging process or for the introduction of the process gases (carrier gas with precursor and further reactant).

In a further embodiment, the process gas analyser has a controllable inlet for the pulsed feeding of the gaseous constituent to be detected to the ion trap. In this case, a controllable inlet is understood to be an inlet which can be opened or closed in a manner dependent on a control signal in order to be able to perform the detection of the gaseous constituent in a pulsed sequence and/or in order to be able to perform the accumulation or desorption of the substance to be detected in predefinable temporal intervals. It goes without saying that the controllable inlet can coincide, if appropriate, with the controllable gas inlet or the controllable gas outlet of the chamber.

In a further embodiment, the total pressure of the residual gas in the interior is more than 10⁻³ mbar, preferably more than 500 mbar, in particular more than 900 mbar (typically up to approximately 1000 mbar). In particular in CVD processes, the total pressure of the residual gas in the interior can be considerable and correspond, if appropriate, to the atmospheric pressure. At such background pressures, conventional process gas analysers fail if they are intended to detect small quantities of a residual gas. With the aid of the ion trap, however, even at a high total pressure, it is possible to detect gaseous constituents even with very low partial pressures in real time. It goes without saying that lower pressures, e.g. 10⁻³ mbar or more, can also be used in the chamber depending on the process respectively used for the surface processing.

In a further embodiment, the partial pressure of the gaseous constituent to be detected in the interior is less than 10⁻⁹ mbar, preferably less than 10⁻¹² mbar, in particular less than 10⁻¹⁴ mbar. Even the detection of gas constituents having such low partial pressures (e.g. with only a few hundred particles per cm³) at high residual gas pressure in the interior can be effected in the manner described above (in real time).

A further aspect is realized in a method for monitoring surface processing on a substrate, comprising: carrying out a residual gas analysis for detecting at least one gaseous constituent of a residual gas atmosphere formed in an interior of a chamber for arranging the substrate, wherein the gaseous constituent to be detected is ionized via an ionization device and is stored for carrying out the residual gas analysis in an ion trap. The ion trap makes it possible to increase the sensitivity during the detection via the process gas analyser. As a result, it is possible to monitor contaminating substances in the background gas and also the concentrations of substances, e.g. dopants, taking part in a chemical reaction with the surface during and/or before the start of the surface processing process and to identify in particular in a timely manner whether a process can be continued or started at all owing to deviations from the target process conditions. In particular, in the case of a deviation from the target process conditions, a warning can be issued to an operator.

The use of an ion trap, in particular an FT ion trap, makes it possible to carry out a “real-time measurement” or a “real-time detection” of the gaseous constituent. In all of the above-described coating methods or removing methods, a fast detection or a fast determination of the quantity/concentration of the substance to be detected with scan times in the seconds range is advantageous for the precise control of the deposition thickness (layer thickness in nanometres) of the applied layer or of the layer removal (e.g. an etching process). The contamination level of selected contaminated constituents (e.g. water or oxygen in the case of nitride deposition) in the residual gas atmosphere can also be determined rapidly and precisely in this way. On the basis of the measured contamination level or the measured concentration of contaminating substances, even before the start of the process it is possible to decide whether the latter is permitted to be started at all, or whether the chamber should be purged, if appropriate. Moreover, via the ion trap mass spectrometer, in particular via the FT ion trap, during critical coating or etching processes in which a plasma is generated, the exact gas composition in the plasma can be monitored or regulated. Intermediate products which arise as a result of the plasma or as a result of evaporation, sputtering, etching, etc. can also be detected and thus allow precise and optimized regulation of the process parameters.

In one variant, an energy provided by the ionization device for ionization is set in a manner dependent on the gaseous constituent to be detected, to put it more precisely, on the ionization energy of the gaseous constituent. This is advantageous in particular in the case of metal organic chemical vapour deposition or in the case of atomic layer deposition in order to ionize metallo-organic compounds in a targeted manner such that only singly cracked metallo-organic ions are generated and detected or monitored. In this way, it is possible to reduce the risk of metal deposition in the process gas analyser and thus to increase the lifetime thereof or the lifetime of the process gas analyser. Moreover, in this way the mass spectrum becomes clearer and thus facilitates the measurement task.

In a further variant, the chamber has a controllable gas inlet and/or a controllable gas outlet driven in a manner dependent on the detected quantity of the gaseous constituent. The gas inlet and/or gas outlet typically have/has a valve that can be opened or closed via a control signal. The valves can be driven in a manner dependent on the measured partial pressure of the detected gas constituent, for example in order to optimize the switching duration of a purging process in the case of atomic layer deposition.

In a further variant, the surface processing comprises removing a coating applied to the substrate, and the at least one detected gaseous constituent is a constituent of the substrate or of the coating. An analysis of the residual gas via the fast and sensitive detection method described above is advantageous in order to detect or avoid overetching during a material removal on the coating, for example during an etching process. The (if appropriate local) overetching or etching-through of a layer to be patterned or of the entire coating can be identified by comparing a current mass spectrum, indicating the concentration of at least one, preferably a plurality of material(s) contained in the substrate or in a respective layer of the coating (or the associated mass numbers), with the mass spectrum of the material of the substrate or of a respective layer. As soon as a signature specific to the substrate appears in the detected mass spectrum, the etching process can be stopped or, if appropriate, continued at a different location of the coating. Via the comparison with the respective layer material or individual constituents of the layer material of a layer of the coating, the progress of the etching process can additionally be monitored. In particular, the fact of reaching an etching stop layer provided in the coating can also be identified in this way.

Further features and advantages of the invention are evident from the following description of exemplary embodiments of the invention, with reference to the figures of the drawing, which show details essential to the invention, and from the claims. The individual features can each be realized individually by themselves or as a plurality in any desired combination in a variant of the invention.

### DRAWING

Exemplary embodiments are illustrated in the schematic drawing and are explained in the description below. In the figures:

FIG. 1 shows a schematic illustration of an apparatus for atomic layer deposition on a substrate,

FIG. 2 shows a schematic illustration of an apparatus for carrying out a plasma etching process on a coated substrate,

FIG. 3 shows a schematic illustration of an FT-ICR trap for a process gas analyser,

FIG. 4 shows a schematic illustration of a Penning trap for carrying out a mass-selective buffer gas cooling method, and

FIGS. 5a-c show schematic illustrations of a process gas analyser with a cooling finger (a) and a gas-binding material (b, c) for sorption and sequent desorption of a gas constituent.

In the following description of the drawings, identical reference signs are used for identical or functionally identical component parts.

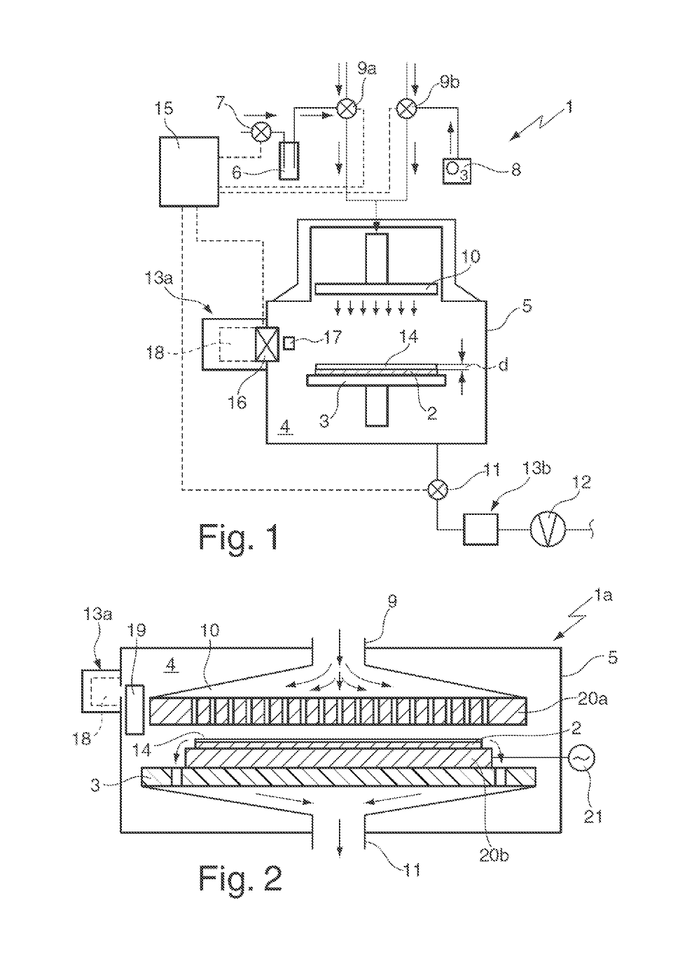

FIG. 1 schematically shows an apparatus 1 for atomic layer deposition on a substrate 2 (here: silicon wafer), arranged on a holder 3 in an interior 4 of a process chamber 5. Both the holder 3 and the walls of the process chamber 5 can be heated to (if appropriate different) temperatures. The holder 3 can be connected to a motor in order to cause the substrate 2 to effect a rotational movement during coating. The apparatus 1 also comprises a container 6 containing a metallo-organic precursor material, which is tetrakis(ethylmethylamino)hafnium (TEMAH) in the present example. In order to bring the precursor material from the container 6 into the process chamber 5, an inert carrier gas, e.g. argon, is used, which can be fed to the container 6 via a controllable valve 7. A further container 8 serves for providing ozone gas O₃ as a reactant during the atomic layer deposition.

The carrier gas with the precursor and the ozone gas can respectively be introduced into the process chamber 5 by a controllable inlet in the form of a controllable valve 9a, 9b. A distribution manifold 10 is arranged in the chamber 5 in order to distribute the incoming gas as homogeneously as possible in the direction of the substrate 2. Via the controllable valves 9a, 9b, a purging gas, e.g. argon, can also be fed to the process chamber 5 in order to purge the process chamber 5 and the respective feed lines. A further controllable valve 11, which forms a gas outlet, is connected to a vacuum pump 12 in order to remove the gases from the process chamber 5. For the purpose of monitoring the residual gas atmosphere in the process chamber 5, a first process gas analyser 13a is flanged to the process chamber 5. A second process gas analyser 13b for monitoring the residual gas is arranged in an extraction line downstream of the outlet valve 11. Both the first and the second process gas analyser 13a, 13b serve for detecting or determining the quantity or the partial pressure of at least one gaseous constituent which is contained in the residual gas atmosphere of the chamber 5 (or was contained in the chamber 5 in the case of the process gas analyser 13b).

For applying a coating 14 composed of hafnium oxide (HfO₂) to the substrate 2, the following procedure is adopted: firstly, the carrier gas with the TEMAH precursor is fed to the process chamber 5 via the first valve 9a. Afterwards, the first valve 9a is switched over and the purging gas is fed to the process chamber 5 via the first valve 9a (cf. arrow) and the gas together with the residues of the carrier gas and/or of the precursor is extracted via the open exit valve 11 via the vacuum pump 12. After purging, the exit valve 11 is closed and ozone gas is introduced into the chamber 5 via the second valve 9b, the ozone gas entering into a chemical reaction with the precursor on the exposed surface of the substrate 2. The chamber 5 is subsequently purged via the purging gas, which is fed to the chamber via the second valve 9b (cf. arrow) and together with the ozone residues and/or reaction products possibly formed is extracted via the vacuum pump 12 with the exit valve 11 open. During the process described above, a monolayer composed of hafnium oxide is deposited on the substrate 2. After the exit valve 11 has been closed, this process can be repeated a number of times, specifically until the HfO₂ coating 14 has attained a desired thickness d.

The time duration for feeding the carrier gas with the precursor, the time duration for feeding the ozone gas and the time duration of the purging process are typically in the seconds range. A control device 15 serves for driving the valves 7, 9a, 9b, 11, in order to switch over between the above-described steps of the deposition process. The control device 15 additionally serves for driving a further valve 16 which connects the process gas analyser 13a to the process chamber 5. It goes without saying that not only can the control device 15 switch over the valves 7, 9a, 9b, 11, 16 between an open position and a closed position, but that, if appropriate, the mass flow which flows through the respective valves 7, 9a, 9b, 11, 16 can also be controlled via the electronic control device 15.

The total pressure of the residual gas in the process chamber 5 is typically between approximately 10⁻³ mbar and 1000 mbar, comparatively high total pressures of more than 500 mbar or more than 900 mbar also being possible. The total pressure in the chamber 5 can be monitored via a pressure sensor (not shown) and can be modified, if appropriate, via the control device 15 by suitable control of the valves 7, 9a, 9b, 11.

The first process gas analyser 13a flanged to the chamber 5 will be described in greater detail below. An ionization device 17 situated in the chamber 5 is disposed upstream of the process gas analyser 13a, the ionization device serving for ionizing gaseous constituents of the residual gas atmosphere. The ionized gas constituents are fed to the process gas analyser 13a, to put it more precisely to an ion trap 18 arranged in the process gas analyser 13a, which can be done using a feed device (not shown) e.g. in the form of an ion optical unit if appropriate in combination with a vacuum tube. The valve 16 assigned to the process gas analyser 13a is opened and closed at suitable instants via the control device 15, in order to make possible a suitable accumulation—pulsed over time—of ions in the ion trap 18. As a result of the accumulation of the ions in the ion trap 18, it is possible to considerably increase the measurement sensitivity during the residual gas analysis. In order to bring about a gas flow of the ionized gas constituents into the ion trap 18, the process gas analyser 13a can be connected to a vacuum pump (not shown). The ions stored in the ion trap 18 can be detected in a mass spectrometer (not shown) integrated into the process gas analyser 13a, or directly in the ion trap 18.

By way of example, an, in particular pulsed, laser can be used as ionization device 17, the laser making it possible to ionize individual gas constituents in the interior 4 via a focussed laser beam. An electron gun (for ionizing gas molecules by impact ionization) or a plasma generator can also be used as ionization device 17. The plasma generator can be designed in particular for generating a plasma even at high pressures (close to atmospheric pressure). For generating an atmospheric pressure plasma, the ionization device 17 can have two electrodes, for example, between which a radio-frequency discharge is ignited in order to generate a corona discharge. The use of a dielectrically impeded radio-frequency discharge or the use of a piezo-material for the plasma excitation is also possible.

In the case of a plasma generator, the energy provided for the ionization can be set, and in particular coordinated with that gas constituent of the residual gas atmosphere which is to be detected, within certain limits by the choice of the energy (voltage and also, if appropriate, frequency) made available for the excitation of the plasma. By way of example, when a high excitation energy is used, an ionization of practically all types of gas molecules of the residual gas atmosphere (broadband ionization) can be effected, or a narrowband ionization of selected molecules can be carried out, wherein in particular the molecules of the carrier gas (e.g. argon) are not ionized. An ionization device 17 in the form of a laser can also be designed for generating a tunable or settable laser wavelength in order to vary the energy provided for the ionization or in order to tune the energy to the ionization energy of the gaseous substance that is respectively to be detected. The same applies to the use of an electron gun, in which the kinetic energy of the electrons can be varied in a targeted manner and coordinated with the desired ionization energy.

As a result of the coordination, those gas constituents (e.g. contaminating substances or process-relevant gas constituents, e.g. the precursor or other reactants) which are intended to be accumulated in the ion trap 18 can be ionized in a targeted manner. In the case of the atomic layer deposition shown in FIG. 1 or in the case of the metal organic chemical vapour deposition, through the choice of the energy used for the ionization, metal organic compounds (e.g. the precursor) can be ionized in a targeted manner such that only singly cracked metal organic ions are generated and thus also detected or monitored. In this way it is possible to reduce the risk of a metal deposition in the process gas analyser 13a and thus to increase the lifetime thereof.

The detection of the gaseous constituents, to put it more precisely the determination of the quantity or of the partial pressure of a respectively detected gaseous constituent can be used for the open-loop or closed-loop control or regulation of the deposition process. By way of example, on the basis of the concentration of the metal organic precursors or of process-relevant reactants such as ozone or, if appropriate, H₂O in the residual gas atmosphere, it is possible to identify when the purging step can be ended (e.g. as soon as the respective partial pressure falls below a predefined limit value). The control unit 15 connected to the process gas analyser 13a in terms of signalling can then open and close the respective inlet valve 9a, 9b and the outlet valve 11 at suitable instants and thus optimize the time duration used for the purging step. It goes without saying that an optimization of the time duration of the two feeding steps described above is analogously possible as well.

With the aid of the process gas analyser 13a, not only is it possible to effect a process optimization during atomic layer deposition, rather it is also possible to carry out an optimization during other coating processes, for example by carrying out a (possibly plasma-enhanced) CVD process, a metal organic CVD process, or during metal organic chemical vapour phase epitaxy, which can typically likewise be carried out in the (if appropriate slightly modified) apparatus 1 from FIG. 1. The same applies to coating processes which are based on physical vapour deposition. In all these cases, the process parameters (temperature, pressure, etc.), can be suitably adapted or optimized on the basis of the detected gas constituents in the residual gas atmosphere.

The use of a process gas analyser 13a with an ion trap 18 can be advantageous not only for applying a coating 14 to the substrate 2 but also for (targeted) removal of a coating 14 from the substrate 2, as will be described below with reference to FIG. 2, which shows a plasma etching apparatus la for reactive ion etching. The substrate 2 can be a silicon wafer, for example, and the coating 14 can be a photoresist that has been treated in a preceding exposure process e.g. in a microlithography apparatus (via UV or EUV radiation). After irradiation, the coating 14 has first regions, the chemical properties of which have not been altered by the exposure, and second regions, at which the chemical properties of the photoresist have been altered on account of the exposure. The first or the second regions can be removed in a targeted manner in the plasma etching apparatus 1a in order to pattern the coating 14.

For this purpose, the plasma etching apparatus 1a comprises a plasma chamber 5 having an interior 4, into which an etching gas is fed for the removal of the coating 14 or of the coating regions to be removed and in which a plasma is generated. In this case, the reactive etching gas is introduced into the plasma chamber 5 via a gas inlet 9 and is guided via an inlet manifold 10 to a first, top electrode 20a, in which a plurality of through-openings are formed in order to distribute the etching gas as homogeneously as possible. The substrate 2 is arranged on a second, bottom electrode 20b, which, for its part, bears on a plate 3 which serves as a holder and in which through-openings for the etching gas are formed marginally alongside the electrode 20b. Via the through-openings, the etching gas can pass to a gas outlet 11 and be discharged from the plasma chamber 5.

In order to generate the plasma, an AC voltage (typically having frequencies in the MHz range) is applied to the bottom electrode 20b, the voltage being generated via a voltage generator 21. In the interspace between the two electrodes 20a, 20b, an etching gas plasma forms in this case, the plasma or the ionization of the etching gas promoting the chemical reaction of the etching gas with the coating 14. It goes without saying that the coating 14 can be provided with an etching barrier (etching stop layer) in specific surface regions in order that the coating 14 can be provided with a predefined structure during etching.

At the plasma chamber 5, a process gas analyser 13a is provided, which comprises, as in FIG. 1, an ion trap 18 that serves for storing gaseous constituents of the residual gas atmosphere formed in the interior 4. Since the etching gas is ionized in the plasma chamber 5 via the electrodes 20a, 20b or the voltage generator 21, a separate ionization device can be dispensed with provided that the ionized gas constituents are transported to the process gas analyser 13a in a suitable manner (e.g. via an ion optical unit 19). It goes without saying that an additional ionization device can also be provided, if appropriate, for selectively ionizing individual gaseous constituents in the interior 4.

The process gas analyser 13a can serve for the open-loop or closed-loop control or regulation of the plasma etching process, wherein overetching, in particular, can be avoided if the process gas analyser 13a is used to identify whether the substrate 2 is attacked or incipiently etched during the etching process. For this purpose, the mass spectrum currently recorded by the process gas analyser 13a can be compared with a signature of the mass spectrum of the substrate material used, e.g. by the relative height of individual peaks of the currently recorded mass spectrum being compared with the signature of the peaks in the mass spectrum of the substrate material, which signature can be stored in a memory device, for example. If correspondence to the signature of the substrate material is identified, the etching method can be terminated and overetching can thus be avoided. It goes without saying that, if appropriate, not just the signature of the substrate material but also the signature of individual constituents of the coating, e.g. of specific layer types of the coating, can be used for the comparison in order to observe the etching progress or, if appropriate, to detect that an etching stop layer provided in the coating has been reached. Ideally, that is to say when overetching is identified particularly rapidly, it is possible, if appropriate, to completely dispense with an etching stop layer.

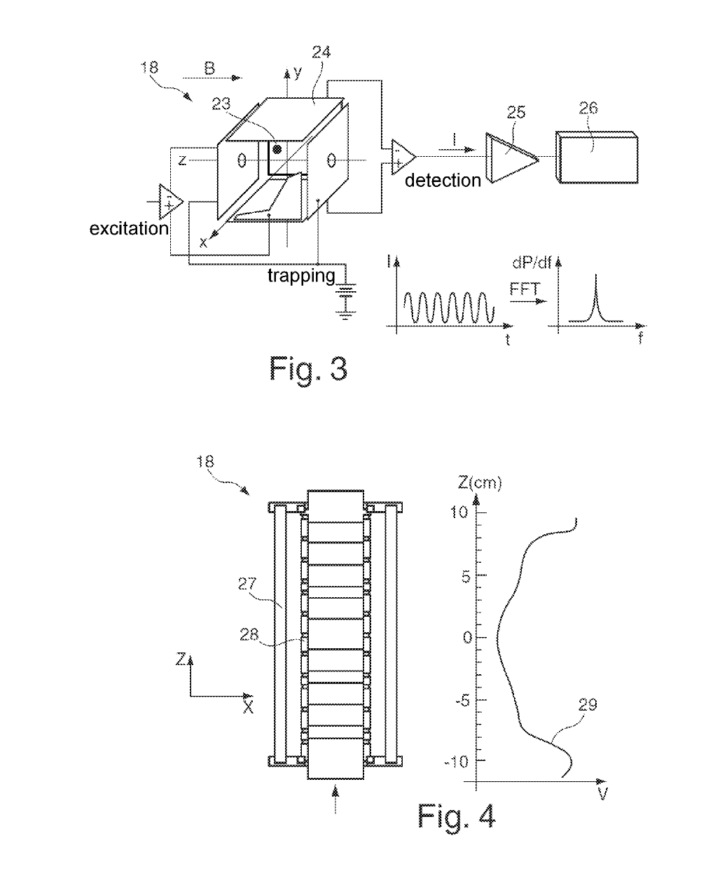

Both when detecting overetching and in the case of the use illustrated in connection with FIG. 1, it is advantageous to obtain and evaluate the mass spectrum as rapidly as possible, ideally in real time, i.e. in a few seconds or milliseconds. In order to achieve this, one particularly suitable type of ion trap 18 is one which is designated as an FT-ICR trap, and which is described in greater detail below in connection with FIG. 3. In the case of the FT-ICR trap 18, the ions 23 are trapped in a homogeneous magnetic field B which runs along the Z-direction of an XYZ coordinate system and forces the ions 23, injected into the FT-ICR trap 18 in the Z-direction, on circular paths with a mass-dependent circulation frequency. The FT-ICR trap 18 furthermore comprises an arrangement having six electrodes 24 (being arranged in three pairs, the two electrodes of a respective pair being spaced apart preferably by 50 cm or less, in particular by 20 cm or less in the corresponding spatial dimension X, Y, Z) to which an alternating electric field is applied perpendicular to the magnetic field B, and a cyclotron resonance is generated in this way. If the frequency of the alternating field radiated in and the cyclotron angular frequency correspond, then the resonance situation occurs and the cyclotron radius of the relevant ion increases as a result of energy being taken up from the alternating field. These changes lead to measurable signals at the electrodes 24 of the FT-ICR trap 18, leading to a current flow I which is fed via an amplifier 25 to an FFT (“fast Fourier transform”) spectrometer 26. The time-dependent current I received in the spectrometer 26 is Fourier-transformed in order to obtain a mass spectrum dependent on the frequency F, which mass spectrum is illustrated at the bottom right in FIG. 3. The FT-ICR trap 18 thus makes it possible to directly detect or directly record a mass spectrum without the use of an additional mass spectrometer, such that a fast residual gas analysis is made possible. Moreover, individual ions or ions having specific mass numbers can be selectively removed from the FT-ICR trap 18, for example by an alternating field being applied to the electrode 24, in order to direct the selected ions to be removed from the trap 18 onto unstable paths. The fast recording of a mass spectrum with the aid of Fourier spectrometry can advantageously be used not only in the case of an ICR trap as described above, but also in the case of other types of ion traps.

As an alternative to the above-described detection of gaseous constituents by the accumulation of ions 23 in FR-ICR cell 18, it is also possible to detect ions directly, that is to say without accumulation, in an ion trap 18 explained below with reference to FIG. 4. FIG. 4 shows an ion trap 18 in the form of a cooling trap of the Penning type such as is used in the experimental set-up ISOLTRAP at Cern (http://isoltrap.web.cern.ch/isoltrap/). A temporally constant magnetic field is generated there via a superconducting magnet (not shown). A constant electric field is generated via a central ring electrode 27 and a plurality of individual electrodes 28 which are arranged in such a way that, along the axis of symmetry of the ion trap 18, an electric field is established, the potential profile 29 of which in the Z-direction is illustrated on the right in FIG. 4 and which has an outer and an inner potential well. Via the so-called mass-selective buffer gas cooling method, in which a cooling gas, e.g. helium, is introduced into the ion trap 18, it is possible, by combining a magnetron excitation via an electric dipole field and a cyclotron excitation via an electric quadrupole field, to effect a spatial separation of ions having a different mass-charge ratio even at a high residual gas pressure in the interior 4 of the respective chamber 5, as is described more comprehensively e.g. in the dissertation by Dr. Alexander Kohl, “Direkte Massenbestimmung in der Bleigegend and Untersuchung eines Starkeffekts in der Penningfalle”, [“Direct mass determination in the vicinity of lead and examination of a Stark effect in the Penning trap”], University of Heidelberg, 1999, which, with regard to this aspect, is incorporated by reference in the content of this application. The ion trap 18 thus serves as a mass filter for spatially separating the gaseous constituent to be detected from further gaseous constituents in the residual gas atmosphere.

Besides the types of ion traps 18 described above, it is also possible to use other types of ion traps, e.g. a Penning trap, a toroidal trap, a quadrupole ion trap or a Paul trap, a linear trap, an Orbitrap, an EBIT or other types of ion traps for storing the gas constituent to be detected. Moreover, it is possible, if appropriate, to arrange a conventional mass filter, e.g. a quadrupole mass filter, upstream of a respective ion trap 18 in order to permit only ions having a predefined mass-charge ratio to enter into the trap. In particular owing to the direct production of a mass spectrum, an FT-ICR trap has proved to be particularly advantageous for the present uses.

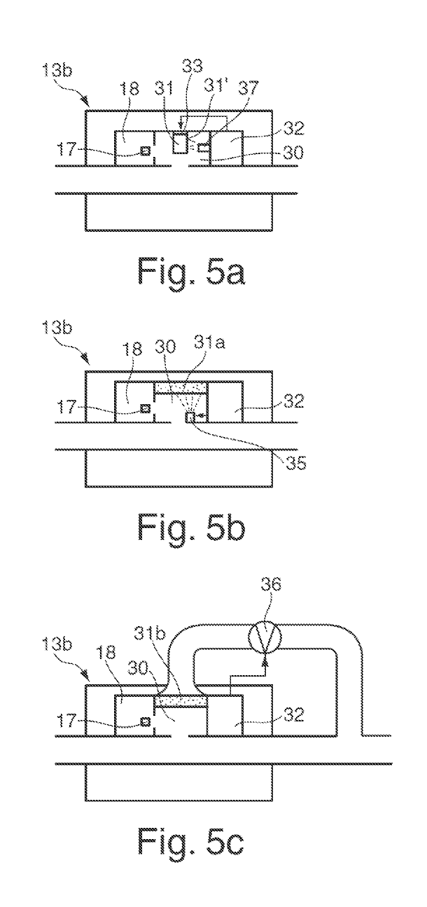

FIGS. 5a-c show examples of embodiments of the process gas analyser 13b from FIG. 1 arranged in the pump channel, in which embodiments the gas constituent to be detected is adsorbed or absorbed prior to ionization, in order to accumulate it, such that, upon the subsequent desorption, a relatively large quantity of the substance to be detected is available for detection.

In FIG. 5a, a further chamber 30, which is separable from the pump channel via a controllable valve (not shown) and in which a cooling finger 31 is fitted, is arranged in the process gas analyser 13b. The cooling finger 31 is connected to a further control device 32, which drives a combined cooling/heating element 33 in order to set the temperature at the surface 31′ of the cooling finger 31 such that at least one gaseous constituent of the residual gas atmosphere that is to be detected freezes out at the surface and can be accumulated in this way. In this case, the temperature of the cooling finger 31 can be set such that individual gas constituents are selectively frozen out and condense on the surface 31′, for example gas constituents which take part as a precursor or as a reactant in the deposition process, but not the background or carrier gas. For this purpose it is necessary for the temperature of the cooling finger 31 to be greater than the condensation temperature of the respective background gas, that is to say above approximately 4.2 K in the case of helium and above approximately 87.3 K in the case of argon.

After accumulation, the valve between chamber 30 and pump channel is closed and, in the small chamber volume, the cooling finger 31 is rapidly thawed or heated in a temperature-controlled manner, such that the gas constituent to be detected can be desorbed from the surface 31′ and be fed to an ion trap 18, in which an ionization device 17 is provided, in order to ionize the accumulated gas constituent for storage, such that the latter if appropriate together with further substances accumulated on the cooling finger 31 can be detected. In addition or as an alternative to the heating of the cooling finger 31 via the combined cooling/heating element 33, it is also possible to desorb the substance or substances to be detected from the surface 31′ by exposing the latter to the focussed radiation from a laser 37, which can be operated in particular in a pulsed fashion.

As an alternative, as is shown in FIG. 5b, the accumulation in the chamber 30 can also be effected at a gas-binding material 31a, e.g. at a zeolite, as a storage or absorber device. For the desorption of the substance to be detected from the gas-binding material 31a, the latter is bombarded via an electron gun 35 (and/or via a laser (not shown)). The electron gun 35 is activated via a control device 32 as soon as a sufficiently long period of time for accumulation has elapsed. The chamber 30 is then separated from the pump channel in the manner described above, in order to detect the desorbed gas constituent to be detected in the ion trap 18 or, if appropriate, in a mass spectrometer (not shown) connected thereto.

While the accumulation takes place passively at the gas-binding material 31a in FIG. 5b, an active accumulation of the substance to be detected can also be effected (cf. FIG. 5c) by the residual gas being pumped, via a pump device 36 through a gas-binding material 31b, which serves as a filter and can likewise consist of a zeolite since this material is porous enough to enable filtering. The pump device 36 can likewise be used for releasing the substance to be detected from the gas-binding material, the pump device being operated in the opposite direction and with a higher capacity for the desorption, such that the substance to be detected is pumped into the chamber 30, where it can be detected in the manner described above in connection with FIGS. 5a,b. It goes without saying that the possibilities illustrated in FIGS. 5a-c for taking up the substance to be detected and subsequently desorbing it can also be combined. In particular, by way of example, the absorption/desorption can also be supported by cooling/heating of the gas-binding material 31a, 31b. Moreover, the ionization device 17 can be arranged, in a manner different from that shown in FIGS. 5a-c, in the chamber 30 rather than in the ion trap 18.

The process gas analysers 13a, 13b can be used to check whether the partial pressures of gas constituents to be detected, for example of metallo-organic compounds or of contaminating substances, are within a tolerance range required in the respective processing process. The use of an ion trap makes it possible, in particular, to detect even extremely small quantities of gaseous constituents in the residual gas atmosphere, the partial pressure of which is less than 10⁻⁹ mbar, less than 10⁻¹² mbar, if appropriate even less than 10⁻¹⁴ mbar. In particular, before the beginning of the surface processing process or of an individual processing step, e.g. while a vacuum is being generated in the interior 4, it is possible to identify whether or not the respective processing process or processing step can be started. As a result of the analysis of the residual gas in the process gas analysers 13a, 13b, it is possible in particular also to deduce the quantity or the partial pressure of individual gas constituents in the interior 4.

To summarize, in the manner described above, it is possible to perform a residual gas analysis for detecting and determining the quantity of gaseous constituents of a residual gas atmosphere during the surface processing on a substrate in situ, even if the residual gas atmosphere has a high background pressure of 500 mbar or more. The residual gas analysis can be effected in particular with a high dynamic range (virtually in real time), yet gas constituents having extremely low concentrations can nevertheless be detected.

1-18. (canceled)

19. An apparatus, comprising:
a chamber enclosing an interior and configured to house a substrate having a surface;
an ionization device configured to ionize a gaseous constituent of a residual gas atmosphere in the interior; and
a process gas analyzer configured to detect the ionized gaseous constituent, the process gas analyzer comprising an ion trap configured to trap the ionized gaseous constituent,
wherein a total pressure of the residual gas in the interior is more than 10⁻³ mbar, and the apparatus is configured to process the surface of the substrate.

20. The apparatus of claim 19, wherein the ionization device is configured to set an energy to ionize the gaseous constituent depending on the gaseous constituent.

21. The apparatus of claim 19, wherein the ionization device is comprises a device selected from the group consisting of a plasma generator, a laser and a field emission device.

22. The apparatus of claim 19, wherein the apparatus is configured to perform at least one process selected from the group consisting of a chemical vapour deposition process, a metal organic chemical vapour phase epitaxy process, an atomic layer deposition process, a physical vapour deposition process and a plasma etching process.

23. The apparatus of claim 19, wherein the ion trap is selected from the group consisting of a Fourier transform ion trap, a Penning trap, a toroidal trap, a quadrupole ion trap, a Paul trap, a linear trap, an Orbitrap, an EBIT and a RF buncher.

24. The apparatus of claim 19, further comprising an ion optical unit between the ionization device and the ion trap.

25. The apparatus of claim 19, wherein the ion trap is configured to accumulate the gaseous constituent.

26. The apparatus of claim 19, wherein the ion trap is configured to isolate the gaseous constituent from other gaseous constituents.

27. The apparatus of claim 19, further comprising a gas-binding material to accumulate the gaseous constituent.

28. The apparatus of claim 19, further comprising a cooling unit configured to cool a surface to freeze out or condense the gaseous constituent.

29. The apparatus of claim 28, further comprising a heating unit configured to desorb the gaseous constituent from the surface.

30. The apparatus of claim 28, further comprising a device to irradiate the surface with light or electron beams to desorb of the gaseous constituent from the surface.

31. The apparatus of claim 19, wherein the chamber comprises a gas inlet controllable depending on a detected quantity of the gaseous constituent.

32. The apparatus of claim 19, wherein the chamber comprises a gas outlet controllable depending on a detected quantity of the gaseous constituent.

33. The apparatus of claim 19, wherein the process gas analyzer comprises a controllable inlet configured to pulse feed the gaseous constituent to the ion trap.

34. The apparatus of claim 19, wherein the partial pressure of the gaseous constituent in the interior is less than 10⁻⁹ mbar.

35. A method, comprising:
using an ionization device to ionize a gaseous constituent of a residual gas atmosphere in an interior of a chamber which is configured to process a surface of a substrate;
using an ion trap to trap the ionized gaseous constituent; and
detecting the ionized gaseous constituent to perform a residual gas analysis.

36. The method of claim 35, using the ionization device to provides an energy to ionize the gaseous constituent depending on the gaseous constituent.

37. The method of claim 35, wherein the chamber comprises a controllable gas inlet driven depending on a detected quantity of the gaseous constituent, and/or the chamber comprises a controllable gas outlet driven depending on a detected quantity of the gaseous constituent.

38. The method of claim 35, further comprising removing a coating from the substrate, wherein the gaseous constituent is a constituent of the substrate or the coating.
